(19) United States
(12) Patent Application Publication
(10) Pub. No.: US 2023/0048934 A1
(43) Pub. Date: Feb. 16, 2023

(54) METHOD FOR MAKING A DRY-TYPE TRANSFORMER, DRY-TYPE TRANSFORMER OBTAINED FROM SAID METHOD, AND DIELECTRIC BARRIER ARRANGEMENT FOR ELECTRICALLY ISOLATING A COIL OF A TRANSFORMER ASSEMBLY

(71) Applicant: Hitachi Energy Switzerland AG, Baden (CH)

(72) Inventors: Antonio NOGUEZ, Zaragoza (ES); Rafael MURILLO, Zaragoza (ES); Carlos ROY, Zaragoza (ES); Lorena CEBRIAN, Zaragoza (ES)

(73) Assignee: Hitachi Energy Switzerland AG, Baden (CH)

(21) Appl. No.: 17/792,721

(22) PCT Filed: Jan. 15, 2021
(86) PCT No.: PCT/EP2021/050865

§ 371 Date: Jul. 14, 2022

(30) Foreign Application Priority Data
Jan. 15, 2020 (EP) 20382020.4

(51) Int. Cl. H01F 27/32; H01F 41/12; H01F 27/08; H01F 27/02; H01F 27/28; G06F 30/23

(52) U.S. Cl. CPC H01F 27/324; H01F 41/125; H01F 27/085; H01F 27/025; H01F 27/2876; G06F 30/23; B33Y 10/00

(57) ABSTRACT

A dry-type transformer, comprises a magnetic core, at least one high voltage (HV) winding, and at least one low voltage (LV) winding inductively coupled to the magnetic core. The transformer is made by determining a shape of an electric field that is generated, 3D printing a dielectric structure shaped to conform to the determined shape of the electric field, and mounting the dielectric structure between the HV and LV windings. A dielectric barrier arrangement for electrically isolating a coil of a transformer assembly from a further coil of the transformer assembly or from a core of the transformer assembly comprises a first dielectric structure having a first cylindrical dielectric structure extending along a longitudinal axis (L).

### CROSS REFERENCE TO RELATED APPLICATIONS

This application is a 35 U.S.C. § 371 national stage application of PCT International Application No. PCT/EP2021/050865 filed on Jan. 15, 2021, which in turns claims foreign priority to European Patent Application No. 20382020.4, filed on Jan. 15, 2020, the disclosures and content of which are incorporated by reference herein in their entirety.

The present disclosure relates to transformers and more particularly to dry-type transformers. The present disclosure also relates to a method for making such transformers. The present disclosure further relates to a dielectric barrier arrangement for electrically isolating a coil of a transformer assembly from a further coil of the transformer assembly or from a core of the transformer assembly.

### BACKGROUND

Transformers are used for converting electricity from a voltage level to electricity at either of higher or lower voltage level in an electrical circuit. Typical transformers comprise two sets of insulated wire wound around a ferromagnetic core forming a high voltage winding (HV winding) and a low voltage winding (LV winding). When electrical power is applied to one winding that draws power from a source of voltage, it is then magnetically transferred to another winding that delivers power to a load at a transformed or changed voltage. The ratio of turns in one winding to the turns in another winding is the same as the ratio of the voltage of the source to the voltage of the load.

Dry-type transformers are known for power distribution networks. They employ no dielectric liquid for insulating the windings. Electrical components in such transformers are required to be insulated completely due to the low dielectric properties of the air. For this purpose, dry-type power transformers use cast epoxy insulated windings. This in practice involves complexity, extra labor time, and thus high costs.

A dielectric structure is provided between components at different voltages, that is, between the HV and LV windings. The dielectric structure may comprise insulating barriers, cylindrical insulating sheets or collars acting as dielectric screens that split an air gap between the windings.

Support blocks made of an insulating material may be provided for supporting the windings. Support blocks can include sheds or insulating barriers perpendicular to the electric field to improve dielectric behavior. Support blocks are made of insulating materials usually by injection molding to withstand voltage drop between their ends, from one side of the windings of the transformer and on the other side of a structure which are grounded.

One or more horizontal insulating screens may be provided in the supporting blocks in order to increase a creepage distance. Thus, in general, manufacture of several parts is required for insulation purposes so, in order to reduce costs, parts having simple shapes are manufactured. They however do not fit the shapes of the components to be insulated or the electric fields. This adversely affects dielectric behavior, for example, due to gaps between the parts, and also risk of power failure. If parts having complex shapes are manufactured, high costs are involved since a great number of different parts are required to be manufactured.

A dry-type transformer having a suitable, efficient and cost-effective dielectric structure is therefore still required.

### SUMMARY

In view of the above problems, the present disclosure provides a method for making a dry-type transformer with which significant advantages are obtained. The dry-type transformer that is made by the present method comprises a winding assembly that includes a magnetic core, at least one high voltage (HV) winding, and at least one low voltage (LV) winding. The windings are inductively coupled to the magnetic core. The core may comprise a column extending along a longitudinal axis, wherein the at least one low voltage winding and the at least one high voltage winding are wound around the longitudinal axis. The core may further comprise a first yoke and a second yoke, wherein the column extends between the first yoke and the second yoke.

According to the method disclosed herein, a shape of an electric field generated in the transformer is determined. Determining a shape of an electric field in the transformer may be carried out by performing an electric finite element method simulation. The geometry is then adapted to the shape of the equipotential lines of the electric field obtained in the simulation for 3D printing the dielectric structure. 3D printing is thus carried out based on said 3D dielectric simulation of the electric field from which 3D geometry for the dielectric structure is designed adapted to the shape of the electric field. Tuning the geometry of the dielectric structure may be performed before being printed so that the dielectric structure can be suitably 3D printed.

A number of 3D printing technologies known in the art may be used for the purposes of the present method. For example, Selective Laser Sintering (SLS) may be employed to make a dielectric structure from a determined shape of the electric field. SLS printing technology provides rapid prototyping and production of component parts. A laser is used as the power source to sinter nylon, polyamide or any suitable powdered material. The laser hits at points in space defined by a 3D model binding the material together to create a solid structure. A further example for printing a dielectric structure from the determined shape of an electric field may be Fused Deposition Modeling (FDM). In FDM printing technology a polymer is melted in moving heated extrusion nozzles and extruded according to a model. Mechanical integrity is achieved by fusing layers with one another upon deposition. In still a further example, stereolithography (SLA) may be employed to make a dielectric structure from the determined shape of said electric field. In SLA a liquid polymer resin is selectively exposed to ultraviolet light causing chemical monomers to link together to form polymers resulting in a three-dimensional solid. In any case. the dielectric structure may preferably be manufactured by 3D printing polymers or composite materials comprising fibers and polymers. Preferably, the dielectric structure is not made of a ceramic material.

A 3D printed dielectric structure is then obtained which is suitably shaped to be mounted between the HV and LV windings and between the HV and structures, such as barriers, or the magnetic core. According to one important feature, the obtained 3D printed dielectric structure is shaped to closely conform to a shape of the electric field in the transformer. The electric field depends on the structure and the characteristics of the transformer where the 3D printed dielectric structure is to be fitted. For example, where the equipotential lines between the windings are parallel to winding surfaces the dielectric structure may be cylindrical in shape, and where the electric field at the winding ends is curved outwards the dielectric structure may be a barrier adapted to the shape of the electric field.

The 3D printed dielectric structure is preferably a one-piece structure. Such one-piece structure may include, for example, horizontal barriers, vertical barriers, supporting blocks, collars, clamps for supporting the magnetic core, etc., all printed into one single piece. Making a dielectric structure into one single piece, resulting in no gaps between the different components. This advantageously makes flashover difficult to passthrough.

An improved dry-type transformer is thus obtained. It comprises at least one first winding, at least one second winding, and at least one of the above mentioned 3D printed dielectric structure, arranged between the at least first and second windings and between the windings and the structures or core of the transformer. The 3D printed dielectric structure comprises at least one cylindrical dielectric screen that is shaped to closely conform to a shape of an electric field that is generated in the transformer. The cylindrical dielectric screen may be arranged between the windings. The cylindrical dielectric screen may have a first substantially even portion to fit in a space defined by a corresponding cylindrical barrier arranged between the windings of the transformer. The cylindrical dielectric screen may also have a second substantially even portion, transversal to the first portion and to a winding, extending outwards from the first portion.

As stated above, the dielectric structure is preferably printed in one-single piece. The dielectric structure also includes at least one supporting block, as stated above, to support the dielectric screen and the windings of the transformer. The above mentioned second substantially even portion of the cylindrical dielectric screen may also extend beyond the supporting blocks.

As describe above, the 3D printed dielectric structure is a one-single piece with no gaps at least between the cylindrical dielectric screen, the supporting blocks, horizontal barriers for isolating the magnetic core, and the transition surfaces between the cylindrical and horizontal screens.

Air ducts may be provided for directing an airflow from at least one cooling fan and distribute it uniformly at least to the windings of the transformer. The air ducts may be formed in the same 3D printing process when making the dielectric structure such that the dielectric structure is obtained in a single piece including said air ducts.

A number of significant advantages has been found to be obtained when putting the present method into practice. The number of parts of the dry-type transformer obtained by the present method is significantly decreased, resulting in reduced installation time and costs. Parts having very complex shapes can be manufactured easily at low cost regardless their geometrical complexity. This allows the design of dielectric structures to be greatly optimized so as to adapt to the electrical field and improve dielectric performance. A dielectric structure with enhanced configuration is provided with surfaces suitably adapted to the electric field which advantageously improves dielectric behavior. Furthermore, different functionalities such as electric, cooling and mechanical are integrated in one single piece.

The dielectric structure can be made of polymers and/or composite materials such as fibers and polymers having an improved performance since no gaps are formed between parts such as barriers, support blocks, horizontal barriers and the transition surfaces between the cylindrical and horizontal screens. The dielectric structure in the present dry-type transformer fits better to parts to be insulated preventing the occurrence of dielectric failures. Also, isolation distances can be reduced thus reducing costs of materials in the transformer. Preferably, the dielectric structure is not made of ceramic.

A further significant advantage derived from the present method and dry-type transformer is that cooling is improved. In known dry-type transformers, fans are provided under the windings at a given distance. In some embodiments, dry-type transformer air is blown by fans through air ducts formed in the dielectric structure itself to flow around the windings and also the ferromagnetic core, in cooling channels inside the windings, between windings and barriers, etc., to the outside. The air ducts formed in the dielectric structure allow for uniform, high air flow rate. Instead, in prior art dry-type transformers most of the air blown by the fan is dispersed and either it does not pass through the cooling channels or reaches them very unevenly with high air flow rate at some points while low air flow rate at other points.

Still a further advantage of the present dry-type transformer is that mechanical support of the windings is improved since the dielectric structure may include the above mentioned supporting blocks for supporting the windings made with complex and mechanically optimized shapes, with varying thicknesses where required. The supporting blocks may be made with any shapes as required while still being resistant enough for supporting the windings, and withstanding forces involved during possible short circuits. The supporting blocks may be finned so as to increase creepage while improving dielectric behavior.

In some embodiments, the first winding defines a longitudinal axis, wherein the at least one dielectric structure further comprises a screen, for example the above-mentioned screen, wherein the screen extends at least substantially perpendicular to the longitudinal axis. The screen may further electrically isolate the first winding and/or the second winding. The screen may be formed in direct contact with the at least one supporting block. The screen may be formed directly adjacent to or connected to or integrally with the cylindrical dielectric screen. The screen may be shaped substantially sheet-like. The sheet may surround the circular dielectric screen sleeve-like with respect to the longitudinal axis.

In some embodiments, the dielectric structure includes a supporting block for supporting the coil or the further coil. For example, the dielectric structure includes two or three or four or more supporting blocks that may be arranged symmetrically around the corresponding cylindrical dielectric structure.

In some embodiments, the at least one dielectric structure further comprises a radially protruding positioning element for radially positioning the at least one dielectric structure relative to a longitudinal axis defined by the first winding. The protruding positioning element may be arranged directly connected to the cylindrical dielectric screen. The positioning element may be formed integrally with the cylindrical dielectric structure of the dielectric structure, e.g., by means of 3D printing.

In some embodiments, the at least one dielectric structure comprises at least two cylindrical dielectric screens, comprising a radially inner cylindrical dielectric screen and a radially outer cylindrical dielectric screen. At least one fluid barrier structure may be provided between the radially inner and the radially outer cylindrical dielectric screen, and may prevent fluid flow along the longitudinal axis along the gap formed between the radially inner and the radially outer cylindrical dielectric screen. The at least one fluid barrier may extend around the whole circumference of the cylindrical dielectric structure, and may extend endlessly, i.e., in a closed loop configuration.

The at least one fluid barrier structure thus may be designed and arranged to close a radial gap formed between the radially inner cylindrical dielectric screen and the radially outer cylindrical dielectric screen in a fluid-tight manner. The fluid barrier element may be integrally formed with the inner and outer cylindrical dielectric screen, e.g. by means of 3D printing.

In some embodiments, the transformer comprises a first dielectric structure having a first cylindrical dielectric screen, and a second dielectric structure having a second cylindrical dielectric screen, wherein the second cylindrical dielectric screen at least partially coaxially surrounds the first cylindrical dielectric screen. The design is particularly such that the second dielectric structure is separate from the first dielectric structure. Thus, not only manufacturing of parts of the transformer assembly is facilitated, but also a particularly simple assembly is enabled.

The transformer may be designed such that the second dielectric structure is separate from the first dielectric structure such that it may be moved relative thereto by a movement along the longitudinal axis, at least in an unassembled state or during assembly.

In some embodiments, the screens of the first and second dielectric structures are arranged at opposite longitudinal ends of the respective first and second dielectric structure, respectively.

In some embodiments, at least one air duct or fluid duct is formed between the at least one dielectric structure and the coil and/or between the at least one dielectric structure and the further coil and/or between the dielectric structure and the core.

For example, the positioning element may circumferentially extend around the first or the second cylindrical dielectric screen in a closed ring-like manner. In this way, a fluid flow parallel to the longitudinal axis between the first cylindrical dielectric screen and the second cylindrical dielectric screen can be prevented, substantially prevented, or at least minimized. This may improve effectiveness of cooling flows along paths directly between the high voltage coil and/or the low voltage coil and the first or second dielectric member, respectively.

The at least one positioning element may thus act as fluid barrier structure and thus may be designed and arranged to close a radial gap formed between the radially inner cylindrical dielectric screen and the radially outer cylindrical dielectric screen in a fluid-tight manner. The fluid barrier element may be integrally formed with the inner and outer cylindrical dielectric screen, e.g. by means of 3D printing.

As discussed above, a radial fluid gap is formed between the first and/or second dielectric structure and the coil, the further coil or the core. Accordingly, any fluid, e.g., air flowing through such a gap in a direction parallel to the longitudinal axis may be used to cool the coil, the further coil, or the core.

The radially inner cylindrical dielectric screen and/or the radially outer cylindrical dielectric screen may be shaped at least substantially cylindrical, as discussed above.

The first cylindrical dielectric structure and/or the second cylindrical dielectric structure each may have for example one, two, three, or four, or five, or six, or even more than six corresponding cylindrical dielectric screens.

According to an additional and/or alternative aspect of the present disclosure, a dielectric barrier arrangement for electrically isolating a coil of a transformer assembly from a further coil of the transformer assembly or from a core of the transformer assembly is provided. The dielectric barrier arrangement comprises a first dielectric structure, and a second dielectric structure, as specified above.

Any of the above-mentioned fluid ducts may be for example designed to guide a cooling fluid in the form of air or another gas.

The first dielectric structure and/or the second dielectric structure may include a fluid opening that is in fluid communication with a fluid duct of the transformer. Thus, a cooling fluid can be suitably guided from outside of the transformer into the one or more fluid ducts via the fluid opening. Also, more than one fluid openings may be provided. A fan, pump or other venting structure may be used for creating a flow of cooling fluid, as mentioned above.

The fluid-opening may be formed at a border between the screen and the first or second cylindrical dielectric structure, respectively. In particular, it may be formed in the screen.

In some embodiments, the at least one cooling fluid duct has, with respect to the longitudinal axis, an opening, respectively at each one of its opposing ends to forming a cooling fluid inlet and cooling fluid outlet. In some embodiments, all further gaps which might be present between the first and second dielectric barrier or between double cylindrical dielectric screens of the dielectric barriers are closed such as to prevent fluid from flowing there along.

In some embodiments, the 3D printed dielectric structure is the first and/or second dielectric structure as described above in connection with the dielectric barrier arrangement.

In some embodiments, the cylindrical dielectric screen and the at least one supporting block of the 3D printed dielectric structure have no gaps, openings or discontinuities.

### BRIEF DESCRIPTION OF THE DRAWINGS

One non-limiting examples of the present disclosure will be described in the following, with reference to the appended drawings, in which:

FIG. 1 is a diagrammatic rear elevational view of a standard dry-type transformer;

FIG. 2 is a front elevational view of the standard dry-type transformer in FIG. 1 where equipotential lines in a XZ plane have been depicted

FIG. 3 is an enlarged side elevational detail view of equipotential lines through supporting blocks;

FIG. 4 is an enlarged sectional view of equipotential lines through supporting blocks in FIG. 3;

FIG. 5 is a diagrammatic front elevational view of a dry-type transformer according to the present disclosure;

FIG. 6 is a representation of an example of a dielectric structure assembly comprising two one-piece 3D printed dielectric structures inserted into one another;

FIG. 7 is a schematic cross-section of a dielectric barrier arrangement, for example the one of FIG. 6, comprising a first and second dielectric structure according to an embodiment of the present disclosure;

FIG. 8 is a perspective view of the dielectric barrier arrangement, for example the one of FIG. 6 or 7, wherein the first and second dielectric structures are separated from each other;

FIG. 9 is a perspective cross-sectional view along line IX-IX indicated in FIG. 7; and

FIG. 10 is a further schematic cross-section of an embodiment of a corresponding transformer assembly.

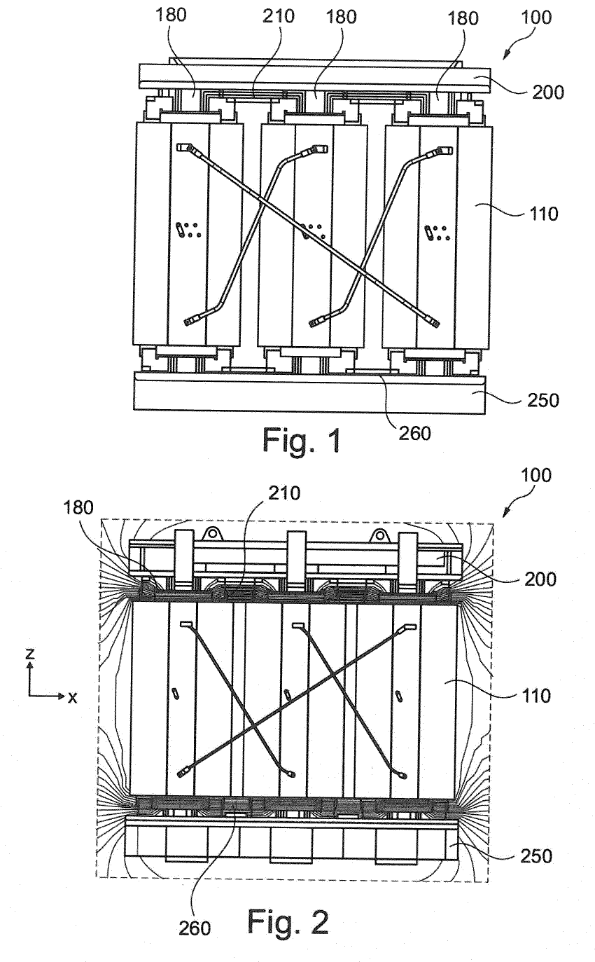

### DETAILED DESCRIPTION

Reference is first made to the non-limiting example shown in figures of the drawings where a dry-type transformer 100 has been illustrated. As shown in figures, the dry-type transformer 100 comprises a winding assembly including a first winding 110, that is a high voltage winding (HV winding), a second winding 120, that is a low voltage winding (LV winding), and a magnetic core 180 around which the HV and LV windings 110, 120 are arranged.

The HV and LV windings 110, 120 are fitted between a top structure 200 and a bottom structure 250 of the transformer 100. The top and bottom structures 200, 250 have associated corresponding top and bottom core yokes 210, 260, respectively.

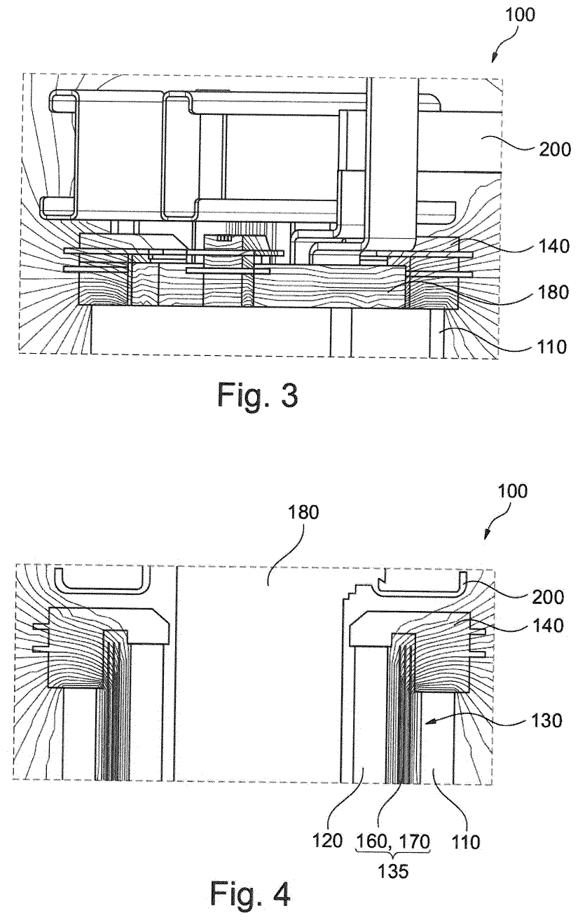

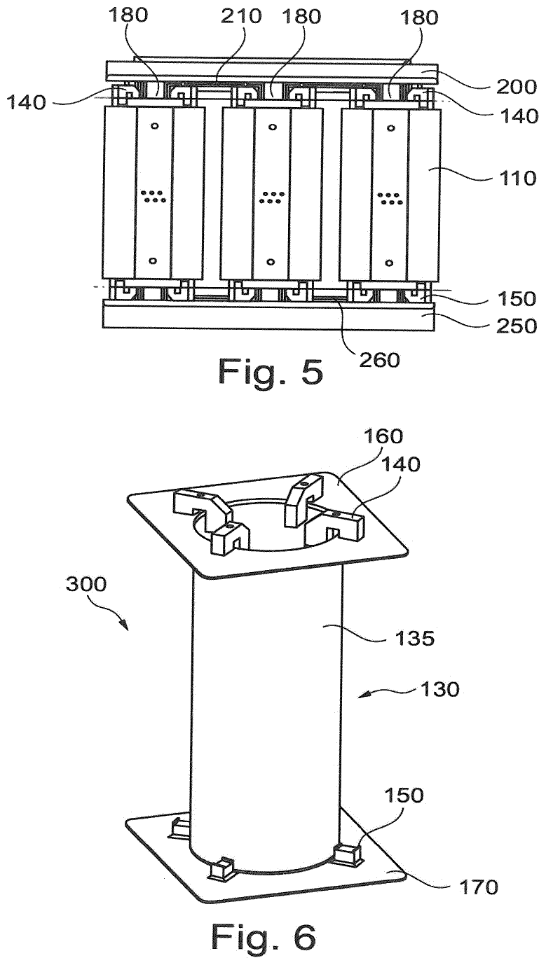

Reference is now made to FIGS. 2-4 of the drawings where the equipotential lines of the dielectric field generated in the transformer 100 are shown. Equipotential lines are perpendicular to the electric field vector and determines the region in the space where every point has the same dielectric potential. The spacing between the lines describes the intensity of the electric field in the transformer. The shape of the electric field depends on the configuration of the transformer 100 and is determined by a 3D simulation from which a dielectric structure 130 is suitably designed. From that 3D simulation of the shape of the electric field a dielectric structure 130 is 3D printed into a single piece by 3D printing polymers or composite materials comprising fibers and polymers and through any of Selective Laser Sintering (SLS), or Fused Deposition Modeling (FDM), or stereolithography (SLA) 3D printing technologies. Other 3D printing technologies are not ruled out.

The shape of the resulting 3D printed dielectric structure 130 closely conforms to the shape of the electric field that has been previously determined in the simulation. The geometry of the dielectric structure 130 is tuned where necessary before being 3D printed.

FIG. 6 shows one example of a dielectric structure assembly 300 comprising a first one-piece 3D printed dielectric structure 130 and a second one-piece 3D printed dielectric structure 130 which is inserted upside down inside the first one-piece 3D printed dielectric structure 130. The 3D printed dielectric structure 130 comprises a cylindrical dielectric screen 135 that is arranged between the HV winding 110 and the LV winding 120. The dielectric structure 130 further includes a corresponding screen 160, 170 arranged between the windings 110, 120 and the core yokes 210, 260, and/or metallic structures (200). Also, the one-piece 3D printed dielectric structure 130 includes top and bottom supporting blocks 140, 150 arranged to support the dielectric screen 135 and the HV and LV windings 110, 120. Since the 3D printed dielectric structure 130 is a one-piece structure, no gaps are present, that is, the cylindrical dielectric screen 135, 160, 170 and the supporting blocks 140, 150 of the dielectric structure 130 have no gaps, openings or discontinuities.

The 3D dielectric structure 130 is 3D includes air ducts (not shown). Such air ducts are suitably designed to direct an airflow from external cooling fans (not shown) into the HV and LV windings 110, 120 and the magnetic core 180 in a distributed and uniform manner for efficient cooling of the transformer 100.

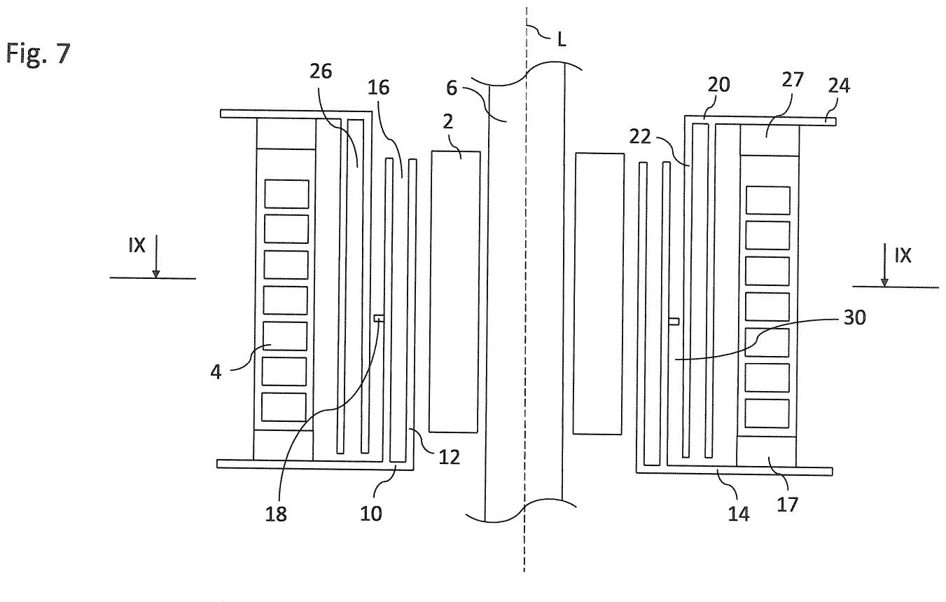

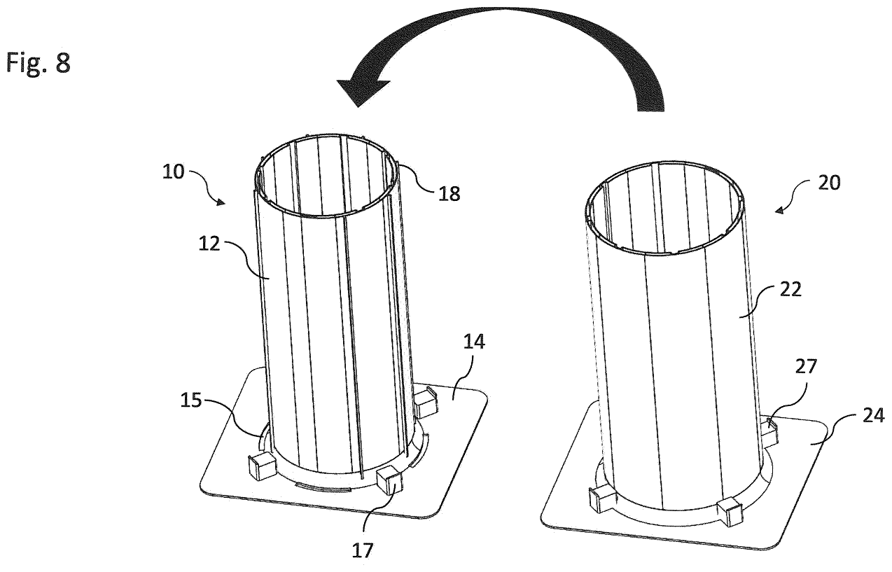

FIG. 7 is a schematic cross-section of a transformer according to an embodiment of the present disclosure. FIG. 8 is a perspective view of a first and a second dielectric structure of the transformer. The first and second dielectric structure are suited for electrically isolating a coil 2 of the transformer from a further coil 4 of the transformer or from a core 6 of the transformer. Unless otherwise stated in the following, the transformer of the transformer assembly may be structured as the above described transformer 100 and may comprise corresponding features, as discussed herein above.

The coil 2 may be a low voltage winding, and the further coil 4 may be a high-voltage winding. The core 6 may comprise a lower yoke and an upper yoke, for example the bottom core yoke 260 and the top core yoke 210, and a column extending between the lower and the upper yoke. The coil 2 and the further coil 4 particularly surround the column of the core 6.

The first dielectric structure 10 comprises a first cylindrical dielectric structure 12 extending along a longitudinal axis L. The second dielectric structure comprises a second cylindrical dielectric structure 22 extending along the longitudinal axis L. The longitudinal axis L extends through the column of the core 6.

The second cylindrical dielectric structure 22 at least partially coaxially surrounds the first cylindrical dielectric structure 12. Alternatively, the first cylindrical dielectric structure may at least partially coaxially surround the second cylindrical dielectric structure. In other words, the second cylindrical dielectric structure 22 and the first cylindrical dielectric structure 12 overlap as seen along the longitudinal axis L. For example, at least one half of the length of the second cylindrical dielectric structure 22 seen along the longitudinal axis L may overlap with at least one half of the length of the first cylindrical dielectric structure 12.

The dielectric barrier arrangement is designed such that the second dielectric structure 20 is separate from the first dielectric structure 10.

The first dielectric structure 10 and/or the second dielectric structure 20 may each be a one-piece or integral structure. Preferably, the first dielectric structure 10 and/or the second dielectric structure 20 is manufactured by 3D printing.

In some embodiments, the first cylindrical dielectric structure 12 and/or the second cylindrical dielectric structure 22 comprises a radially protruding positioning element 18 for radially positioning the second cylindrical dielectric structure 22 relative to the first cylindrical dielectric structure 12. This may facilitates the assembling of the transformer further. The radially protruding element 18 particularly extends, with respect to the longitudinal axis L, circumferentially in closed ring-like manner. In this way, a fluid flow between the first and second cylindrical dielectric structure 12, 22 may be effectively prevented or at least significantly reduced.

In particular, one dielectric structure 10; 20 may be inserted upside down inside the other dielectric structure 20; 10.

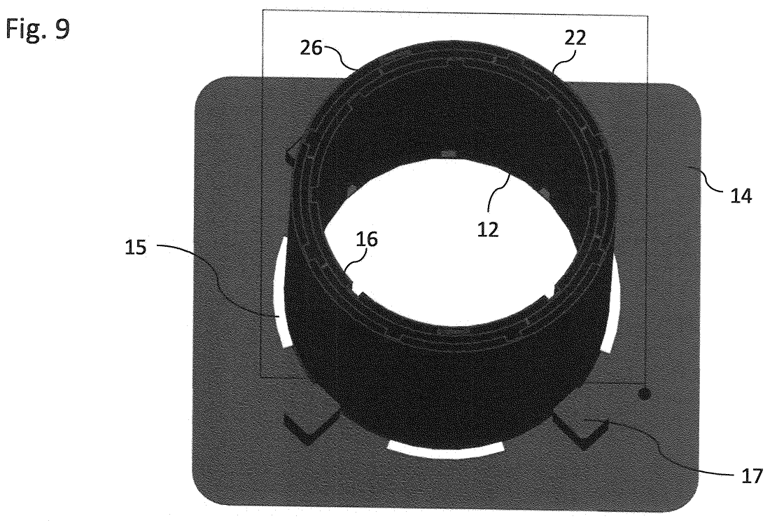

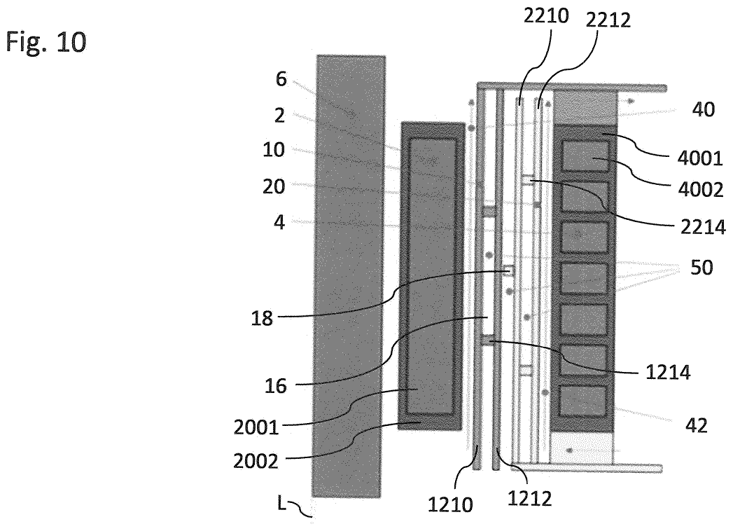

FIG. 9 is a perspective cross-sectional view through cylindrical dielectric structures 12 and 22 along line IX-IX indicated in FIG. 7. As seen for example in this figure, the first cylindrical dielectric structure 12 may be, at least partly, double-walled with a radially inner and a radially outer cylindrical dielectric screen. FIG. 10 is a schematic cross-sectional view showing a corresponding radially inner cylindrical dielectric screen 1210 of the first cylindrical dielectric structure 12, a radially outer cylindrical dielectric screen 1212 of the first cylindrical dielectric structure 12, a radially inner cylindrical dielectric screen 2210 of the second cylindrical dielectric structure 22, and a radially outer cylindrical dielectric screen 2212 of the second cylindrical dielectric structure 22.

Further, the first dielectric structure 10 particularly has at least one fluid barrier element 1214 extending circumferentially, wherein the at least one fluid barrier element 1214 is designed and arranged to close a radial gap formed between the radially inner cylindrical dielectric screen 1210 and the radially outer cylindrical dielectric screen 1212 of the first tubular section 12 in a fluid-tight manner. Similarly, the second dielectric structure 20 particularly has at least one fluid barrier element 2214 extending circumferentially, wherein the at least one fluid barrier element 2214 is designed and arranged to close a radial gap formed between the radially inner cylindrical dielectric screen 2210 and the radially outer cylindrical dielectric screen 2212 of the second tubular section 22 in a fluid-tight manner.

More generally, the first cylindrical dielectric structure 12 and/or the second cylindrical dielectric structure 22 may have at least two cylindrical dielectric screens, for example three, four, five, six or even more corresponding cylindrical dielectric screens. Between each pair of adjacent cylindrical dielectric screens, a radial gap may be formed which is closed by a corresponding fluid barrier element.

As can be seen in FIG. 10, a first cooling fluid duct 40 may be formed between the dielectric barrier arrangement and the coil 2 and a second cooling fluid duct 42 may be formed between the dielectric barrier arrangement and the further coil. Thus, an effective cooling of the coil and the further coil is enabled. Corresponding cooling fluid flows are indicated in FIG. 10 by arrows. A fluid flow inlet and a fluid flow outlet may be formed for example between supporting blocks.

Further, the first dielectric structure 10 and/or the second dielectric structure 20 may include a fluid opening 15 that is in fluid communication with the first or second fluid duct 40, 42.

As can be seen in FIG. 10, the coil 2 may comprise a conductor 2001 and an isolation member 2002 at least partly surrounding the conductor 2001 for isolating the conductor 2001. The isolation member 2002 may be made for example from epoxy resin. Similar, the further coil 4 may comprise a conductor 4001 and an isolation member 4002 at least partly surrounding the conductor 4001 for isolating the conductor 4001. The isolation member 4002 may be made for example from epoxy resin. The dielectric structure, which is preferably not made of ceramic, is separate from such isolation member and, preferably, made of a different material than the isolation member.

The first dielectric structure 10 further comprises a sleeve-like screen 14 extending at least substantially perpendicular to the longitudinal axis L for further electrically isolating the coil 2 and/or the further coil 4. The screen 14 is preferably sheet-like shaped, extending perpendicular to the longitudinal axis L. Similar, the second dielectric structure 20 further comprises a sleeve-like screen 24 extending at least substantially perpendicular to the longitudinal axis L for further electrically isolating the coil 2 and/or the further coil 4. The screen 24 of the second dielectric structure 20 is preferably sheet-like shaped, extending perpendicular to the longitudinal axis L.

Preferably, the screens 14, 24 of the first and second dielectric structures 10, 20 are arranged at opposite longitudinal ends of the respective first and second dielectric structure 10, 20, respectively. In other words, the screen 14 of the first dielectric structure 10 and the screen 24 of the second dielectric structure are arranged at opposite ends of the dielectric barrier arrangement.

The screen 14 of the first dielectric structure 10 preferably includes a supporting block 17 for supporting the coil 2 or the further coil 4. Similar, the screen 24 of the second dielectric structure 20 preferably includes a supporting block 27 for supporting the coil 2 or the further coil 4.

The invention furthermore relates, for example, to the following additional and/or alternative aspects:

1. A method for making a dry-type transformer (100), the transformer (100) comprising a winding assembly including a magnetic core (180), at least one high voltage winding (110), and at least one low voltage winding (120) inductively coupled to the magnetic core (180), the method comprising:
determining a shape of an electric field that is generated in the transformer (100);
3D printing a dielectric structure (130) shaped to conform to the determined shape of the electric field; and
mounting the dielectric structure (130) between the high voltage and low voltage windings (110, 120).

2. The method of aspect 1, wherein determining a shape of an electric field in the transformer is carried out by performing an electric finite element method simulation and then adapting the geometry of the dielectric structure (130) to the shape of the equipotential lines of the electric field obtained in the electric simulation.

3. The method of aspect 1 or 2, wherein it further comprises:
tuning the geometry of the dielectric structure (130) before being printed.

4. The method of any of the preceding aspects, wherein the 3D printed dielectric structure (130) is a one-piece structure.

5. The method of preceding aspect 4, wherein the dielectric structure (130) is made by 3D printing polymers or composite materials comprising fibers and polymers.

6. The method of preceding aspects 4 or 5, wherein the dielectric structure (130) is made by at least one of the Selective Laser Sintering, Fused Deposition Modeling, or Stereolithography 3D printing technologies.

7. A dry-type transformer (100), comprising at least one first winding (110, 2), at least one second winding (120, 4), and at least one 3D printed dielectric structure (130, 10, 20) provided between the at least first and second windings (110, 120, 2, 4), the dielectric structure (130, 10, 20) comprising at least one cylindrical dielectric screen (135, 12, 22) shaped to closely conform to a shape of an electric field that is generated in the transformer (100), and at least one supporting block (140, 150, 17, 27) to support the dielectric screen (135, 10, 20) and the first winding (110, 2) and/or second winding (120, 4).

8. A dry-type transformer (100) of aspect 7, made by the method according to any one of aspects 1 to 6.

9. A dry-type transformer (100) according to aspect 7 or 8, wherein at least one screen (160, 170, 14, 24) is arranged between the at least one winding (110, 120, 2, 4), and core yokes (210, 260), and/or metallic structures.

10. A dry-type transformer (100) according to any of the aspects 7-9, wherein the dielectric structure (130, 10, 20) is printed in one-single piece with no gaps at least between the cylindrical dielectric screen (135, 12, 22), the supporting blocks (140, 150, 17, 27) and the cylindrical dielectric screen (135, 12, 22) between the windings (110, 120, 2, 4), and the screen (160, 170, 17, 27) between the at least one winding (110, 120, 2, 4) and core yokes (210, 260), and/or metallic structures (200).

11. A dry-type transformer (100) according to any of the aspects 7-10, further including air ducts (40, 42) for directing an airflow from at least one cooling fan and distribute it uniformly at least to the windings (110, 120, 2, 4).

12. A dry-type transformer (100) according to any of the aspects 7-11, wherein the dielectric structure (130, 10, 20) is made by 3D printing polymers or composite materials comprising fibers and polymers.

13. A dry-type transformer according to any of the aspects 7-12, wherein the dielectric structure (130, 10, 20) is made by at least one of the Selective Laser Sintering, Fused Deposition Modeling, or Stereolithography 3D printing technologies.

14. A dry-type transformer according to any of the aspects 7-13, wherein the first winding (110, 2) defines a longitudinal axis (L), wherein the at least one dielectric structure (130, 10, 20) further comprises a screen (160, 170, 14, 24), extending at least substantially perpendicular to the longitudinal axis (L) for further electrically isolating the first winding (110, 2) and/or the second winding (120, 4), preferably wherein the screen (160, 170, 14, 24) is formed directly connected to the at least one supporting block (140, 150, 17, 27).

15. A dry-type transformer according to any of the aspects 7-14, wherein the at least one dielectric structure (130, 10, 20) comprises a radially protruding positioning element (18) for radially positioning the at least one dielectric structure (130, 10, 20) relative to a longitudinal axis (L) defined by the first winding (110) and/or for closing a fluid duct.

16. A dry-type transformer according to any of the aspects 7-15, wherein the at least one dielectric structure (130, 10, 20) has at least two cylindrical dielectric screens, comprising a radially inner cylindrical dielectric screen (1210, 2210) and a radially outer cylindrical dielectric screen (1212, 2212), wherein a radial gap or duct (16) is formed between the radially inner cylindrical dielectric screen (1210, 2210) and the radially outer cylindrical dielectric screen (1212, 2212).

17. A dry-type transformer according to aspect 16, wherein the at least one dielectric structure (130, 10, 20) further comprises at least one fluid barrier structure (1214, 2212) that is designed and arranged to close the radial gap or duct (16) in a fluid-tight manner.

18. A dry-type transformer according to any of the aspects 7-15, wherein the at least one dielectric structure (130, 10, 20) further includes a fluid opening (15) fluidly connected to a fluid or air duct (40, 42) of the transformer.

19. A dry-type transformer according to any of the aspects 7-18, comprising a first dielectric structure (130, 10) having a first cylindrical dielectric screen (12), and a second dielectric structure (130, 20) having a second cylindrical dielectric screen (22), wherein the second cylindrical dielectric screen (22; 135) at least partially coaxially surrounds the first cylindrical dielectric screen (12; 135), wherein the design is such that the second dielectric structure (20; 130) is separate from the first dielectric structure (10; 130).

20. A dry-type transformer of aspect 19, wherein the screens (24, 14; 160, 170) of the first and second dielectric structures (10, 20; 130) are arranged at opposite longitudinal ends of the respective first and second dielectric structure (10, 20; 130), respectively.

21. A dry-type transformer of any of the aspects 7-20, wherein an air duct or fluid duct (40, 42) is formed between the at least one dielectric structure (130, 10, 20) and the coil (2) and/or between the at least one dielectric structure (130, 10, 20) and the further coil (4) and/or between the dielectric structure (130, 10, 20) and the core (6).

Although only a number of examples have been disclosed herein, other alternatives, modifications, uses and/or equivalents thereof are possible. Furthermore, all possible combinations of the described examples are also included herein. Thus, the scope of the present disclosure should not be limited by particular examples but should be determined only by a fair reading of the claims that follow. Reference signs related to drawings placed in parentheses in the claims are solely for attempting to increase the intelligibility of the claim and shall not be construed as limiting the scope.

1. A method for making a dry-type transformer, the transformer comprising a winding assembly including a magnetic core, at least one high voltage winding, and at least one low voltage winding inductively coupled to the magnetic core, the method comprising:
determining a shape of an electric field that is generated in the transformer;
3D printing a dielectric structure shaped to be aligned with the shape of the equipotential lines of the electric field; and
mounting the dielectric structure between the high voltage and low voltage windings.

2. The method of claim 1, wherein determining a shape of an electric field in the transformer is carried out by performing an finite element method simulation and then adapting the geometry of the dielectric structure to the shape of the equipotential lines of the electric field obtained in the electric simulation.

3. The method of claim 1, wherein the 3D printed dielectric structure is a one-piece structure, preferably wherein the dielectric structure is made by 3D printing polymers or composite materials comprising fibers and polymers.

4. The method of claim 3, wherein the dielectric structure is made by at least one of the Selective Laser Sintering, Fused Deposition Modeling, or Stereolithography 3D printing technologies.

5. A dry-type transformer, comprising at least one first winding, at least one second winding, a magnetic core and at least one 3D printed dielectric structure provided between the at least first and second windings, the dielectric structure comprising at least one cylindrical dielectric screen shaped to be aligned with the shape of the equipotential lines of an electric field that is generated in the transformer, and at least one supporting block to support the dielectric screen and the first winding and/or second winding.

6. A dry-type transformer, comprising at least one first winding, at least one second winding, a magnetic core and at least one 3D printed dielectric structure provided between the at least first and second windings, the dielectric structure comprising at least one cylindrical dielectric screen shaped to be aligned with the shape of the equipotential lines of an electric field that is generated in the transformer, and at least one supporting block to support the dielectric screen and the first winding and/or second winding, made by the method according to claim 1.

7. A dry-type transformer according to claim 5, wherein at least one screen is arranged between the at least one winding, and core yokes, and/or metallic structures.

8. A dry-type transformer according to claim 5, wherein the dielectric structure is printed in one-single piece with no gaps at least between the cylindrical dielectric screen, the supporting blocks and the cylindrical dielectric screen between the windings, and the screen between the at least one winding and core yokes, and/or metallic structures.

9. A dry-type transformer according to claim 5, further including air ducts for directing an airflow from at least one cooling fan and distribute it uniformly at least to the windings.

10. A dry-type transformer according to claim 5, wherein the dielectric structure is made by 3D printing polymers or composite materials comprising fibers and polymers.

11. A dry-type transformer according to claim 5, wherein the first winding defines a longitudinal axis (L), wherein the at least one dielectric structure further comprises a screen, extending at least substantially perpendicular to the longitudinal axis (L) for further electrically isolating the first winding and/or the second winding, preferably wherein the screen is formed directly connected to the at least one supporting block and/or directly connected to the cylindrical dielectric screen of the at least one dielectric structure.

12. A dry-type transformer according to claim 5, wherein the at least one dielectric structure comprises a radially protruding positioning element for radially positioning the at least one dielectric structure relative to a longitudinal axis (L) defined by the first winding.

13. A dry-type transformer according to claim 5, wherein the at least one dielectric structure has at least two cylindrical dielectric screens, comprising a radially inner cylindrical dielectric screen and a radially outer cylindrical dielectric screen, wherein a radial gap or duct is formed between the radially inner cylindrical dielectric screen and the radially outer cylindrical dielectric screen.

14. A dry-type transformer according to claim 13, wherein the at least one dielectric structure further comprises at least one fluid barrier structure that is designed and arranged to close the radial gap or duct in a fluid-tight manner.

15. A dry-type transformer according to claim 5, comprising a first dielectric structure having a first cylindrical dielectric screen, and a second dielectric structure having a second cylindrical dielectric screen, wherein the second cylindrical dielectric screen at least partially coaxially surrounds the first cylindrical dielectric screen, and
wherein the design is such that the second dielectric structure is separate from the first dielectric structure.

16. A dry-type transformer of claim 15, wherein the screens of the first and second dielectric structures are arranged at opposite longitudinal ends of the respective first and second dielectric structure, respectively.

17. A dry-type transformer of claim 5, wherein an air duct or fluid duct is formed between the at least one dielectric structure and the coil and/or between the at least one dielectric structure and the further coil and/or between the dielectric structure and the core.

18. The method of claim 2, wherein the 3D printed dielectric structure is a one-piece structure, preferably wherein the dielectric structure is made by 3D printing polymers or composite materials comprising fibers and polymers, and
wherein the dielectric structure is made by at least one of the Selective Laser Sintering, Fused Deposition Modeling, or Stereolithography 3D printing technologies.

19. A dry-type transformer according to claim 5, comprising a first dielectric structure having a first cylindrical dielectric screen, and a second dielectric structure having a second cylindrical dielectric screen,
wherein the second cylindrical dielectric screen at least partially coaxially surrounds the first cylindrical dielectric screen,
wherein the design is such that the second dielectric structure is separate from the first dielectric structure,
wherein the screens of the first and second dielectric structures are arranged at opposite longitudinal ends of the respective first and second dielectric structure, respectively,
wherein the screens of the first and second dielectric structures are arranged at opposite longitudinal ends of the respective first and second dielectric structure, respectively, and
wherein an air duct or fluid duct is formed between the at least one dielectric structure and the coil and/or between the at least one dielectric structure and the further coil and/or between the dielectric structure and the core.
